(19) United States
(12) Patent Application Publication
(10) Pub. No.: US 2014/0062525 A1
(43) Pub. Date: Mar. 6, 2014

(54) INVERTER-DRIVEN ROTARY ELECTRIC MACHINE, INSULATION INSPECTION METHOD AND INSULATION INSPECTION APPARATUS

(71) Applicant: Koji Obata, Tokyo (JP)

(72) Inventor: Koji Obata, Tokyo (JP)

(73) Assignee: Hitachi Automotive Systems, Ltd.

(21) Appl. No.: 14/112,128

(22) PCT Filed: Apr. 26, 2011
(86) PCT No.: PCT/JP2011/060166

§ 371 Date: Nov. 13, 2013

(51) Int. Cl. G01R 31/34

(52) U.S. Cl. CPC G01R 31/346
USPC 324/765.01

(57) ABSTRACT

Insulation inspection method for an inverter-driven rotary electric machine includes: a step of applying, to an insulation sample (2), first impulse voltage simulating a voltage which occurs between winding turns of a rotary electric machine upon application of an inverter surge voltage to measure the number of times Nₜ₋ₜ that an impulse voltage is applied until the insulation sample (2) suffers from insulation breakdown; a step of applying the first impulse voltage to the insulation sample(2) to measure an occurrence frequency n_{pd} of partial discharge which occurs per one time application; step of applying a second impulse voltage simulating the inverter surge voltage to a rotary electric machine (3) to measure a partial discharge occurrence frequency n_{pd(motor)} between the winding turns which occurs per one time application; and determining that an insulation performance of the rotary electric machine (3) is acceptable.

### TECHNICAL FIELD

The present invention relates to a rotary electric machine driven by an inverter (specifically an inverter-driven rotary electric machine having a rated voltage of 700 Vrms or less), and an insulation inspection method and an insulation inspection apparatus for the rotary electric machine.

### BACKGROUND ART

In recent years, operating a rotary electric machine in variable speeds using an inverter is carried out actively from the view point of energy saving. However, it has been reported that, when a rotary electric machine is driven by an inverter, various problems arise at insulating parts of the rotary electric machine (Non-Patent Document 1). For example, it has been reported that, if a steep voltage (inverter surge voltage) generated when a switching element inside of an inverter turns ON/OFF propagates along a cable and reaches a terminal of the rotary electric machine, then mismatching takes places in surge impedance between the cable and the rotary electric machine, as a result of which the voltage across the terminal of the rotary electric machine jumps to a magnitude of twice inverter output voltage.

Further, it has been reported that, if a steep inverter surge voltage arrives at the inside of the rotary electric machine, then a high voltage is shared at a coil on the end leading side of a rotary electric machine winding or between winding turns in the coil. For the inverter-driven rotary electric machine, therefore, it is necessary to make the insulation design so as to withstand such inverter surge voltages and inspect the fabricated rotary electric machine to find whether or not it has a predetermined dielectric strength.

Incidentally, organic insulating materials are generally used in a low-voltage rotary electric machine having a voltage of 700 Vrms or less. Since such organic insulating materials are poor in resistance to partial discharge (PD), there is the possibility that, if the rotary electric machine is used in a condition under which partial discharge will occur, dielectric breakdown may occur in a comparatively short period of time. Therefore, such an insulation design as permits partial discharge not to occur during operation is conventionally adopted for the low-voltage rotary electric machines having a voltage of 700 Vrms or less.

Specifically, the rotary electric machine is insulated in such designs that insulation parts between winding turns, between phases of the rotary electric machine and between the rotary electric machine and the ground have an increased insulation thickness so that partial discharge inception voltages (PDIV) across the insulation parts are higher than voltages applied to the insulation parts of the rotary electric machine upon operation to thereby prevent such partial discharge. Meanwhile, upon inspection of the rotary electric machine fabricated in this manner, a sine wave voltage or an impulse voltage is applied to the rotary electric machine ensure that no partial discharge occurs at any of the insulation parts between the winding turns, between the phases of the rotary electric machine and between the rotary electric machine and the ground. For example, Non-Patent Document 2 discloses such an insulation design and inspection testing method as just described. Further, Patent Document 1 or the like discloses a partial discharge measuring method to be used in this instance, for example.

### Prior Art Documents

### Patent Document

Patent, Document 1: JP-2009-115505-A

### Non-Patent Documents

Non-Patent Document 1: Technical Report of the Institute of Electrical Engineers of Japan, No. 739, p.12 to 20

Non-Patent Document 2: IEC60034-18-41

### SUMMARY OF THE INVENTION

### Problem to be Solved by the Invention

In recent years, together with speeding up of a switching element of an inverter, the rise time period tr of the inverter output voltage has been shortened. The voltage shared between winding turns of an inverter-driven rotary electric machine has increased accordingly, resulting in the possibility that partial discharge may occur between the winding turns. However, since it is assumed that a low-voltage rotary electric machine does not suffer from partial discharge as described above, there is neither insulation design nor an inspection method to be applied in a condition under which such partial discharge will occur.

### Means for Solving the Problem

According to a first embodiment of the present invention, there is provided an inverter-driven rotary electric machine. In an insulation sample which is formed from an insulated wire same as that of a winding of the rotary electric machine and indicates an N-V characteristic in which the number of times that an impulse voltage is applied till insulation breakdown at a voltage peak value V is N, the number of times that an impulse voltage is applied till insulation breakdown when a first impulse voltage is applied is represented by Nₜ₋ₜ. The first impulse voltage simulates a voltage which occurs between winding turns of the rotary electric machine upon application of an inverter surge voltage. Also, an occurrence frequency of partial discharge which occurs per one time application is represented by n_{pd}. In this case, a partial discharge occurrence frequency n_{pd(motor)} between the winding turns is set so as to satisfy, with respect to a required number of times N_{required} that an impulse voltage is applied, the following expression (A1):

n_{pd(motor)}≦Nₜ₋ₜ·n_{pd}/N_{required} (A1)

According to a second embodiment of the present invention, in the inverter-driven rotary electric machine according to the first embodiment, the number of times N_{required} that an impulse voltage is applied is preferably set so as to satisfy, where an occurrence frequency of the inverter surge voltage per a unit time period is represented by nᵢₙᵥ and an operating time period required for the rotary electric machine is represented by tᵢₙᵥ, the following expression (A2):

N_{required}nᵢₙᵥ·tᵢₙᵥ (A2)

According to a third embodiment of the present invention, in the inverter-driven rotary electric machine according to the first or second embodiment, a rated voltage is set to a value of 700 Vrms or less.

According to a fourth embodiment of the present invention, there is provided an insulation inspection method for an inverter-driven rotary electric machine. The method includes a step of applying, to an insulation sample which is formed from an insulated wire same as that of a winding of the rotary electric machine and indicates an N-V characteristic in which the number of times that an impulse voltage is applied till insulation breakdown at a voltage peak value V is N, a first impulse voltage simulating a voltage which occurs between winding turns of the rotary electric machine upon application of an inverter surge voltage to measure the number of times Nₜ₋ₜ that an impulse voltage is applied until the insulation sample suffers from insulation breakdown. The method further includes a step of applying the first impulse voltage to the insulation sample to measure an occurrence frequency n_{pd} of partial discharge which occurs per one time application, and a step of applying a second impulse voltage simulating the inverter surge voltage to the rotary electric machine to measure a partial discharge occurrence frequency n_{pd(motor)} between the winding turns which occurs per one time application. The method further includes determining that an insulation performance of the rotary electric machine is acceptable when the partial discharge occurrence frequency n_{pd(motor)} satisfies the following expression (A1) with respect to the number of times N_{required} that an impulse voltage is applied required for the rotary electric machine:

n_{pd(motor)}≦Nₜ₋ₜ·n_{pd}/N_{required} (A1)

According to a fifth embodiment of the present invention, in the insulation inspection method for an inverter-driven rotary electric machine according to the fourth embodiment, the number of times N_{required} that an impulse voltage is applied is preferably set so as to satisfy, where an occurrence frequency of the inverter surge voltage per a unit time period is represented by nᵢₙᵥ and an operating time period required for the rotary electric machine is represented by tᵢₙᵥ, the following expression (A2):

N_{required}≧nᵢₙᵥ·tᵢₙᵥ (A2)

According to a sixth embodiment of the present invention, there is provided an insulation inspection apparatus for an inverter-driven rotary electric machine. The apparatus includes a storage section in which the number of times Nₜ₋ₜ that an impulse voltage is applied until an insulation sample which uses an insulating wire same as that of a rotary electric machine winding suffers from insulation breakdown and an occurrence frequency n_{pd} of partial discharge which occurs per one time application are stored. The number of times Nₜ₋ₜ that an impulse voltage is applied and the partial discharge occurrence frequency n_{pd} are measured when a first impulse voltage simulating a voltage which appears between winding turns of the rotary electric machine upon application of an inverter surge voltage is applied to the insulation sample. The apparatus further includes an impulse power supply configured to apply a second impulse voltage simulating the inverter surge voltage to the rotary electric machine, and a measurement section configured to measure a partial discharge occurrence frequency n_{pd(motor)} between the winding turns of the rotary electric machine to which the second impulse voltage is applied. The apparatus still further includes an acceptance decision processing section configured to determine that an insulation performance of the rotary electric machine is acceptable when the partial discharge occurrence frequency n_{pd(motor)} satisfies the following expression (A1) with respect to the number of times N_{required} that an impulse voltage is applied required for the rotary electric machine:

n_{pd(motor)}≦Nₜ₋ₜ·n_{pd}/N_{required} (A1)

According to a seventh embodiment of the present invention, there is provided an insulation inspection apparatus for an inverter-driven rotary electric machine. The apparatus includes an impulse power supply capable of selectively outputting one of a first impulse voltage simulating a voltage which is generated between winding turns of a rotary electric machine upon application of an inverter surge voltage and a second impulse voltage simulating the inverter surge voltage. The apparatus further includes a changeover mechanism configured to switchably connect, to the impulse power supply, one of an insulation sample and the rotary electric machine, the insulation sample being formed from an insulated wire same as that of a winding of the rotary electric machine and indicating an N-V characteristic in which the number of times that an impulse voltage is applied till insulation breakdown at a voltage peak value V is N. The apparatus further includes an insulation sample characteristic measurement section configured to measure the number of times Nₜ₋ₜ that an impulse voltage is applied and an occurrence frequency n_{pd} of partial discharge which occurs per one time application, the number of times Nₜ₋ₜ that an impulse voltage is applied and the occurrence frequency n_{pd} being obtained by applying the first impulse voltage to the insulation sample. The apparatus further includes a rotary electric machine characteristic measurement section configured to measure the partial discharge occurrence frequency n_{pd(motor)} obtained by applying the second impulse voltage to the rotary electric machine. The apparatus further includes an acceptance decision processing section configured to determine that an insulation performance of the rotary electric machine is acceptable when the partial discharge occurrence frequency n_{pd(motor)} satisfies the following expression (A1) with respect to the number of times N_{required} that an impulse voltage is applied required for the rotary electric machine:

n_{pd(motor)}≦Nₜ₋ₜ·n_{pd}/N_{required} (A1)

According to an eighth embodiment of the present invention, in the insulation inspection apparatus for an inverter-driven rotary electric machine according to the sixth or seventh embodiment, the number of times N_{required} that an impulse voltage is applied is preferably set so as to satisfy, where an occurrence frequency of the inverter surge voltage per a unit time period is represented by nᵢₙᵥ and an operating time period required for the rotary electric machine is represented by tᵢₙᵥ, the following expression (A2):

N_{required}≧nᵢₙᵥ·tᵢₙᵥ (A2)

### Effect of the Invention

According to the present invention, an inverter-driven rotary electric machine which has an appropriate insulation performance and allows occurrence of partial discharge can be provided.

### BRIEF DESCRIPTION OF THE DRAWINGS

FIG. 1 is a view showing an embodiment of an insulation inspection apparatus according to the present invention.

FIG. 2 is a view showing a testing circuit when a twisted-pair wire sample 2 is tested.

FIG. 3 is a view showing a testing circuit when a motor 3 is tested.

FIG. 4 is a flow chart illustrating an insulation inspection flow for the motor 3.

FIG. 5 is a view illustrating a V-N characteristic of the twisted-pair wire sample 2.

FIG. 6 is a view illustrating an n_{pd}-V characteristic of the twisted-pair wire sample 2.

FIG. 7 is a view illustrating an N·n_{pd}-V characteristic of the twisted-pair wire sample 2.

FIG. 8 is a view illustrating an n_{pd}-ΔV characteristic of the motor 3.

FIG. 9 is a view illustrating an n_{pd}-V characteristic of the motor 3.

FIG. 10 is a flow chart illustrating a detailed process at step S011.

FIG. 11 is a view illustrating a motor terminal voltage waveform simulation.

FIG. 12 is a view illustrating motor terminal voltage waveform measurement.

FIG. 13 is a view illustrating a steep voltage variation amount ΔV₍ₘₒₜₒᵣ₎.

FIG. 14 is a view illustrating an inverter surge n-ΔV characteristic.

FIG. 15 is a view illustrating an inverter surge n·tᵢₙᵥ-V characteristic.

FIG. 16 is a view in which examination contents carried out in the insulation inspection flow are summarized.

FIG. 17 is a view illustrating the lifetime of motors whose insulation inspection is carried out using an insulation inspection method of the present embodiment.

### MODE FOR CARRYING OUT THE INVENTION

As described hereinabove, in recent years, together with speeding up of a switching element of an inverter, the rise time period tr of an inverter output voltage has been and is being shortened. Therefore, the voltage shared between winding turns of an inverter-driven rotary electric machine has increased, resulting in the possibility that partial discharge may occur between the winding turns.

For such a problem as just described, a partial discharge-resistant enamel wire (generally called corona-resistant enamel wire, inverter surge-resistant wire or the like) which has a fixed resisting property to partial discharge and has a survival benefit of the insulation lifetime has been developed, and the likelihood that occurrence of partial discharge can be permitted has come out. Further, even where a partial discharge-resistant enamel wire is not used, in an automotive motor for use with an electric vehicle (EV), a hybrid vehicle (HEV) or the like which is driven only in a short period of time in comparison with conventional low-voltage motors for general industrial use, there is the possibility that occurrence of partial discharge may be permitted if a predetermined required lifetime is satisfied.

In this manner, in recent years, a situation in which even such a low-voltage rotary electric machine is operated in a condition in which partial discharge occurs has arisen. However, since it has been assumed that a low-voltage rotary electric machine does not suffer from partial discharge, insulation design or an inspection method in a condition in which such partial discharge occurs is not available.

On the other hand, a high-voltage rotary electric machine whose rated voltage is to a value of 700 Vrms or more has conventionally been used in a circumstance in which partial discharge occurs. In a high-voltage rotary electric machine, mica (inorganic insulator) having a high resisting property to partial discharge has been used as an insulation material through the ages. Generally, a high-voltage rotary electric machine which uses mica has a very long lifetime even in a situation in which partial discharge occurs. Further, since the inclination of a V-t characteristic is great, insulation lifetime design with a high likelihood is possible. Further, since a high likelihood can be achieved, if fabrication process management of the temperature, humidity, pressure and so forth is carried out appropriately, then even if products vary in lifetime characteristic thereamong, a required lifetime can be satisfied sufficiently.

In contrast, since a low-voltage rotary electric machine does not use mica, such likelihood design cannot be anticipated, and it is necessary to precisely grasp the lifetime characteristic of individual fabricated products and remove an unacceptable product which does not satisfy the predetermined lifetime characteristic. However, a lifetime test (destructive test) cannot be carried out using an actual product. Further, even if insulation design or inspection test of a high-voltage rotary electric machine which has permitted occurrence of partial discharge till now as described above is taken into consideration, insulation design or testing of a low-voltage rotary electric machine which permits occurrence of partial discharge cannot be carried out.

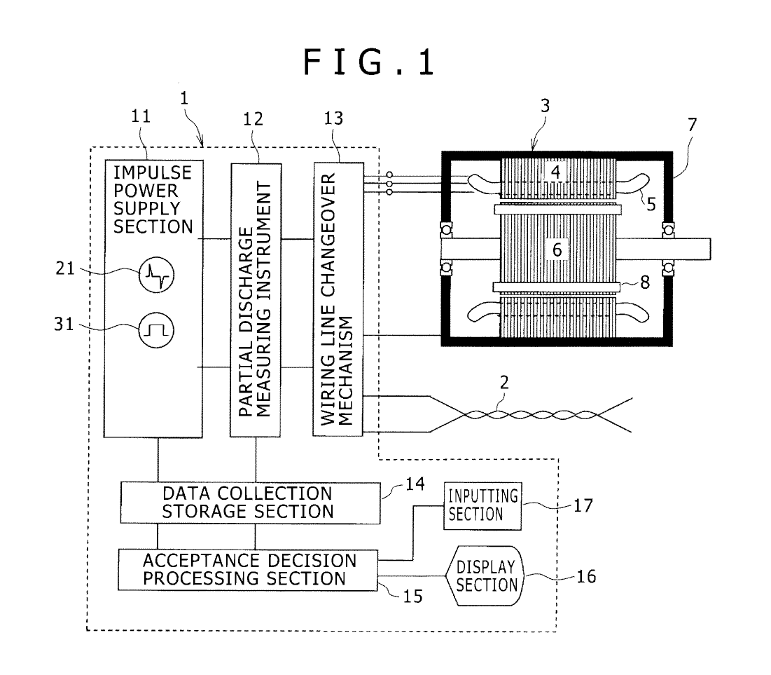

In the following, a mode for carrying out the present invention is described with reference to the drawings. FIG. 1 is a view showing an embodiment of an insulation inspection apparatus according to the present invention. An insulation inspection apparatus 1 includes an impulse power supply section 11, a partial discharge measuring instrument 12, a wiring line changeover mechanism 13, a data collection storage section 14, an acceptance decision processing section 15, a display section 16 and an inputting section 17. Reference numeral 2 denotes a twisted-pair wire sample. Reference numeral 3 denotes a low-voltage rotary electric machine for being driven by an inverter which is a target of an inspection, and in the following description, the low-voltage rotary electric machine is referred to merely as motor.

The motor 3 includes a stator coil 5 which produces a rotating magnetic field, a stator 4 in which the stator coil 5 is accommodated, and a rotor 6 which is rotated by the rotating magnetic field. It is to be noted that, where the motor is an induction motor, a secondary winding is inserted, but where the motor is a permanent magnet synchronous motor, a magnet is inserted, at the position indicated by a reference numeral 8. The rotor 6 and the stator 4 of the motor 3 are accommodated in a frame 7. It is to be noted that, while the motor 3 in a state in which the rotor 6 is inserted is shown in FIG. 1, since the target of the inspection is the stator coil 5, the testing can be carried out also in a state in which the rotor 6 is not inserted.

The impulse power supply 11 can selectively output a bipolar alternating impulse voltage 21 and an impulse voltage 31 which simulates an inverter surge voltage. The impulse power supply 11 is connected to the wiring line changeover mechanism 13 through the partial discharge measuring instrument 12. The twisted-pair wire sample 2 and the motor 3 are connected to the wiring line changeover mechanism 13. The wiring line changeover mechanism 13 distributes an output line of the partial discharge measuring instrument 12 to the twisted-pair wire sample 2 or the motor 3. The connection is changed over by the wiring line changeover mechanism 13.

The twisted-pair wire sample 2 is an element model (insulation sample) which simulates an insulation part between winding turns of the motor 3, and in the example illustrated in FIG. 1, two twisted enamel wires used for motor windings are used. Alternatively, a parallel winding wire sample or a like sample may be used instead.

The magnitude of a test voltage applied to a sample (twisted-pair wire sample 2 or motor 3) from the impulse power supply 11 and a partial discharge signal measured by the partial discharge measuring instrument 12 when a test voltage is applied are stored into the data collection storage section 14. It is to be noted that, although description of a measuring method of partial discharge by the partial discharge measuring instrument 12 is omitted herein, a known method disclosed, for example, in Non-Patent Document 1 or 2, JP-2007-232517-A or a like document is used. The acceptance decision processing section 15 carries out an acceptance decision of an insulation test of the motor 3 based on the data stored in the data collection storage section 14. An acceptance decision method is hereinafter described. The display section 16 is configured using a liquid crystal display, a CRT or a like apparatus and displays an acceptance decision result of the insulation test of the motor 3.

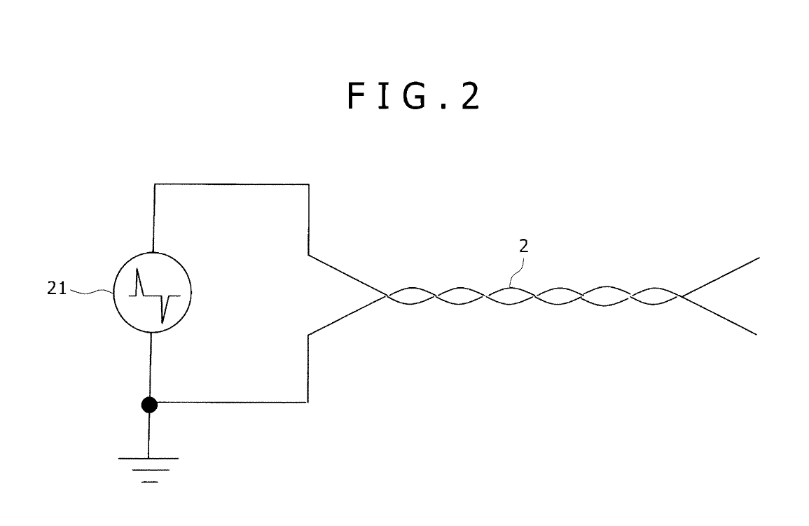

As described hereinabove, the insulation inspection apparatus 1 can carry out a test of the twisted-pair wire sample 2 or a test of the motor 3 by changing over the wiring line changeover mechanism 13. FIG. 2 shows a test circuit when the twisted-pair wire sample 2 is tested, and

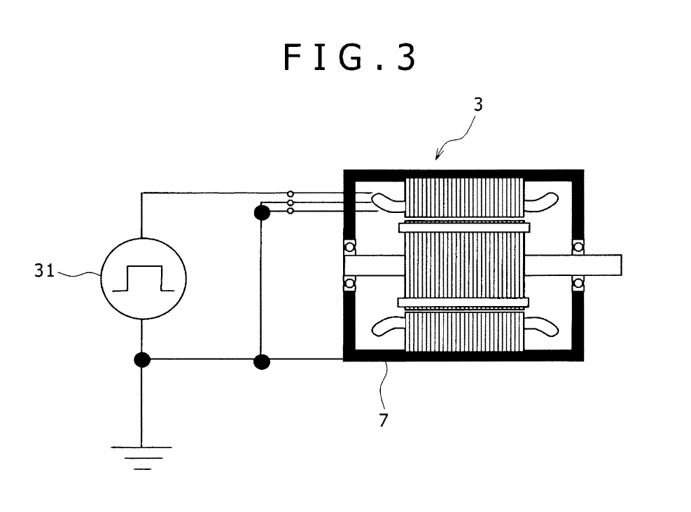

FIG. 3 shows a test circuit when the motor 3 is tested. In the test of the twisted-pair wire sample 2, the bipolar alternating impulse voltage 21 is applied to one of the two wires while the other is grounded as seen in FIG. 2. It is known that, if an inverter surge voltage is applied to the motor winding, then a bipolar alternating impulse of a narrow pulse width is generated between winding turns. On the other hand, in the test of the motor 3, the impulse voltage 31 which simulates an inverter surge voltage is applied to a test target phase of three phases of U, V and W of the stator coil 5 while the other phases and the frame 7 are grounded.

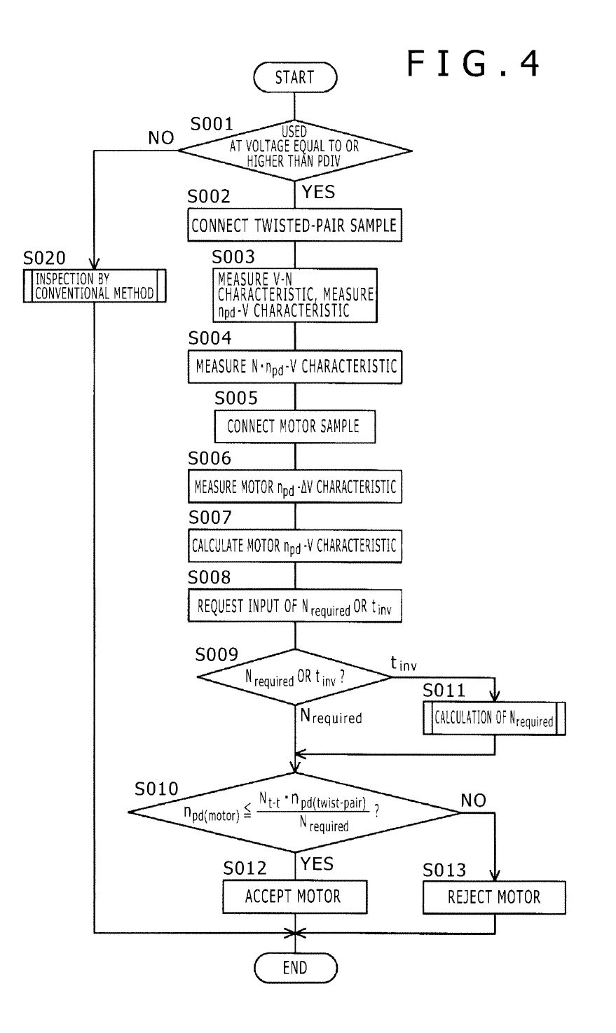

FIG. 4 illustrates an insulation inspection flow of the motor 3 in which the insulation inspection apparatus 1 is used. At step S001, it is determined whether or not an insulation part between winding turns of the motor 3 as a specimen is to be used at a voltage equal to or higher than a partial discharge inception voltage (PDIV). If the motor 3 is to be used at a voltage lower than the PDIV, then the processing advances to step S002, at which such a motor partial discharge test and a PD (partial discharge) free check as in a conventional method are carried out to confirm that no partial discharge occurs. Since the inspection at step S002 is carried out by the conventional method, details thereof are not described herein.

On the other hand, if an insulation part between winding turns of the motor 3 is to be used at a voltage equal to or higher than the PDIV, then the processing advances to step S003. At step S003, the twisted-pair wire sample 2 which is a sample which simulates the insulation part between winding turns of the motor 3 is used to carry out measurement of a V-N characteristic and an n_{pd}-V characteristic which indicate insulation characteristics of the insulated wire.

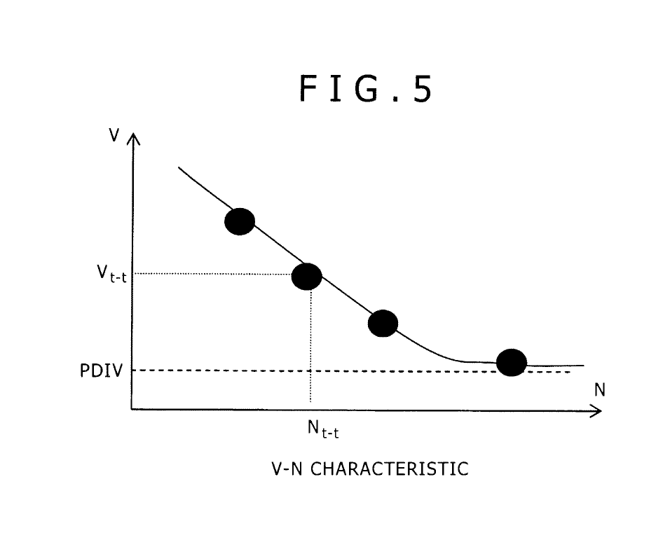

FIG. 5 is a view illustrating the V-N characteristic. This V-N characteristic is obtained in the following manner. The bipolar alternating impulse voltage 21 of an applied voltage V is applied repetitively to the twisted-pair wire sample 2 to measure the number of times N that an impulse voltage is applied until the sample (twisted-pair wire sample 2) suffers dielectric breakdown. By carrying out such a measurement as just described with regard to a plurality of applied voltages V (V≧PDIV), such a V-N characteristic curve as illustrated in FIG. 5 is obtained. A dark round mark in FIG. 5 indicates measurement data.

It is to be noted that, in the acceptance decision hereinafter described (refer to the expression (1) hereinafter given), a decision is carried out using a partial discharge total number Nₜ₋ₜ·n_{pd(twist-pair)} at an applied voltage Vₜ₋ₜ (voltage peak value when an impulse voltage ΔV simulating an inverter surge voltage is applied). Therefore, necessary data are only data (Nₜ₋ₜ, n_{pd(twist-pair)}) relating to the applied voltage Vₜ₋ₜ. However, where a single measurement value is used, since it is not definite whether or not the measurement value represents an appropriate V-N characteristic, data at a plurality of points are measured to confirm that the data are appropriate.

It is to be noted that Vₜ₋ₜ illustrated in FIG. 5 is a voltage peak value which is generated between winding turns when the impulse voltage LV simulating an inverter surge voltage is applied to the motor 3. Meanwhile, Nₜ₋ₜ indicates the number of times that an impulse voltage is applied until dielectric breakdown occurs when the voltage Vₜ₋ₜ is applied to the twisted-pair wire sample 2.

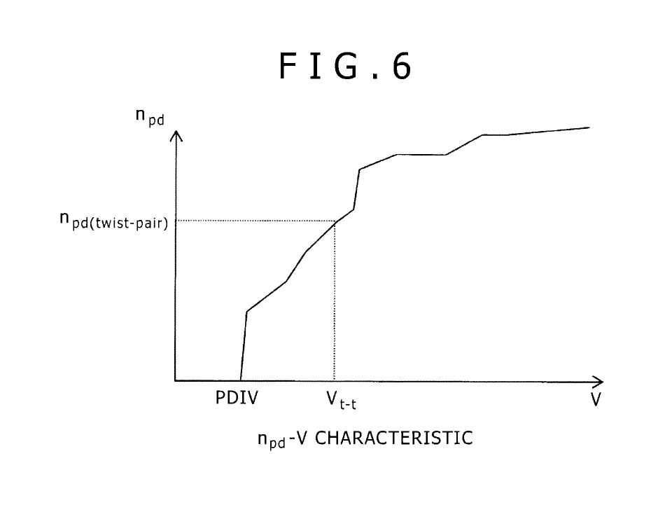

FIG. 6 is a view illustrating an n_{pd}-V characteristic. The n_{pd}-V characteristic is obtained by measuring the number of times n_{pd(twist-pair)} of partial discharge generated per one time application of an impulse voltage when the bipolar alternating impulse voltage 21 of the applied voltage V is applied to the twisted-pair wire sample 2. In the following description, n_{pd (twist-pair)} is hereinafter referred to as partial discharge occurrence frequency. For example, while the bipolar alternating impulse voltage 21 is applied repetitively, the applied voltage V is raised from 0 V to a predetermined voltage higher than and the partial discharge occurrence frequency n_{pd(twist-pair)} which occurs thereupon is measured. As seen in FIG. 6, when the applied voltage V is lower than the partial discharge inception voltage PDIV, no partial discharge occurs, but if the applied voltage V exceeds the PDIV, then partial discharge begins to occur. As the applied voltage increases, also the partial discharge occurrence frequency n_{pd(twist-pair)} increases.

The dielectric breakdown of the twisted-pair wire sample 2 at the applied voltage Vₜ₋ₜ does not simply depend only on the number of times Nₜ₋ₜ that an impulse voltage is applied but is influenced also by the partial discharge occurrence frequency n_{pd(twist-pair)} at the applied voltage Vₜ₋ₜ. In other words, it is considered that the dielectric breakdown depends upon the total number of times of partial discharge until dielectric breakdown occurs. Therefore, if an insulation sample which exhibits a lower partial discharge occurrence frequency n_{pd(twist-pair)} at the applied voltage Vₜ₋ₜ is used, then the number of times Nₜ₋ₜ that an impulse voltage is applied at the applied voltage Vₜ₋ₜ increases.

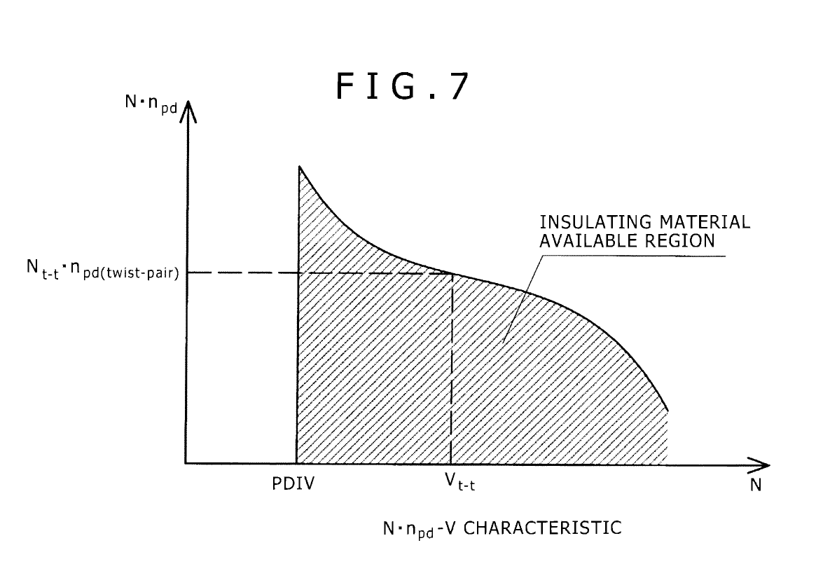

Therefore, at step S004, the number of times N that an impulse voltage is applied until dielectric breakdown occurs and the partial discharge occurrence frequency n_{pd} are multiplied at an equal voltage to determine an N·n_{pd}-V characteristic. A point (Vₜ₋ₜ, Nₜ₋ₜ·n_{pd(twist-pair)}) on the N·n_{pd}-V characteristic curve illustrated in FIG. 7 represents the impulse voltage Vₜ₋ₜ when dielectric breakdown occurs and the total number Nₜ₋ₜ·n_{pd(twist-pair)} of partial discharge until the dielectric breakdown occurs. At a point on the lower side of the point (Vₜ₋ₜ, Nₜ₋ₜ·n_{pd(twist-pair)}), the total number of partial discharge is smaller than Nₜ₋ₜ·n_{pd(twist-pair)}. In particular, a region indicated by hatched lines on the lower side of the N·n_{pd}-V characteristic curve represents a region in which no dielectric breakdown occurs, or in other words, an insulating material available region of the twisted-pair wire sample 2. In the present embodiment, this N·n_{pd}-V characteristic is used to carry out an inspection of the motor 3.

At step 5005, in order to carry out a test of the motor 3, the wiring line changeover mechanism 3 is changed over to establish such a connection scheme as illustrated in FIG. 3. Then at step 5006, the impulse voltage ΔV simulating an inverter surge voltage is applied to the motor 3 to measure the n_{pd}-ΔV characteristic of the motor 3. For example, while the magnitude of the impulse voltage ΔV is changed, the number of times of partial discharge per one time application of the impulse voltage is measured as a partial discharge occurrence frequency n_{pd(motor)}. In the measurement, the increment of the voltage is reduced particularly in the proximity of an inverter surge voltage ΔV₍ₘₒₜₒᵣ₎ estimated to be applied to the motor 3 when the motor 3 is operated by the inverter to measure the occurrence frequency.

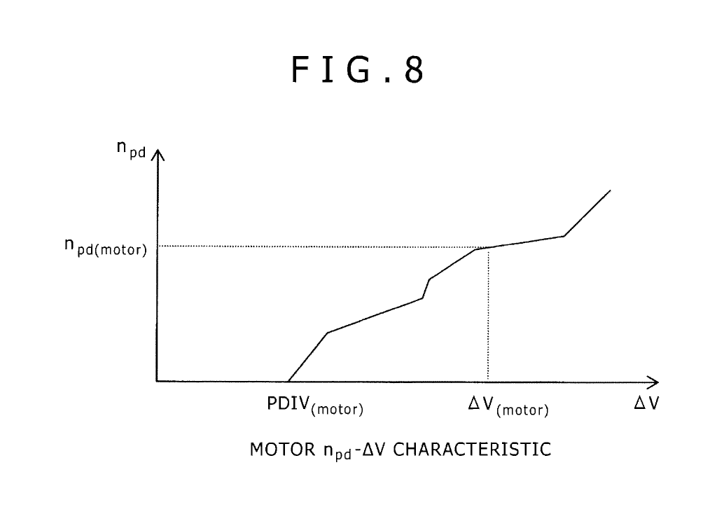

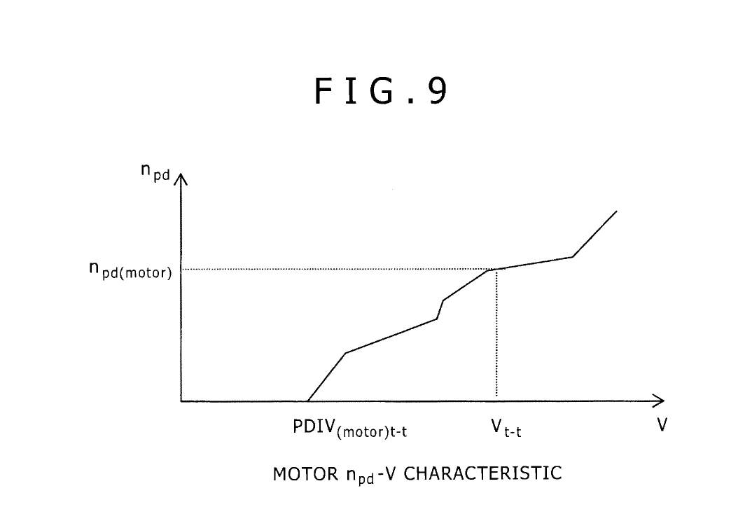

The voltage V shared between the motor winding turns when the inverter surge voltage ΔV₍ₘₒₜₒᵣ₎ is applied to the motor 3 is represented as V=α(tr)·ΔV₍ₘₒₜₒᵣ₎ using a voltage sharing rate α(tr). Therefore, at step S007, this voltage sharing rate α(tr) is used to calculate a motor n_{pd}-V characteristic (refer to FIG. 9) where the axis of abscissa in FIG. 8 is converted into the winding turn sharing voltage V. It is to be noted that the voltage sharing rate α(tr) is a value unique to the motor winding, and the magnitude thereof varies in response to the voltage rise time tr of the inverter surge voltage ΔV₍ₘₒₜₒᵣ₎ and has a value within a range of 1<α(tr)≧1.

At step S008, the insulation inspection apparatus 1 causes the display section 16 to display a screen image which urges an operator to input the number of times N_{required} that an impulse voltage is applied or a motor lifetime tᵢₙᵥ required for the motor 3. At step S009, it is determined whether the number of times N_{required} that an impulse voltage is applied or the motor lifetime is inputted by the operator. Then, if the number of times N_{required} that an impulse voltage is applied is inputted, then the processing advances to step S010. If the motor lifetime tᵢₙᵥ is inputted, then the processing advances to step S011.

First, a case in which the number of times N_{required} that an impulse voltage is applied is inputted is described. At step S010, the insulation inspection apparatus 1 determines, from the n_{pd}-V characteristic illustrated in FIG. 9 and the voltage peak value Vₜ₋ₜ between the winding turns which appears when a predictable inverter surge voltage ΔV (ₘₒₜₒᵣ) is applied to the motor 3, the partial discharge occurrence frequency n_{pd(motor)} at the voltage peak value Vₜ₋ₜ. Then, it is determined whether or not the inputted number of times N_{required} that an impulse voltage is applied and the partial discharge occurrence frequency n_{pd(motor)} of the motor 3 satisfy an acceptance decision conditional expression given as the following expression (1):

n_{pd(motor)}≦Nₜ₋ₜ·n_{pd (twist-pair)}/N_{required} (1)

As described hereinabove, the condition for dielectric breakdown of the twisted-pair wire sample 2 is the partial discharge total number N·n_{pd (twist-pair)} until dielectric breakdown occurs. It is considered that also dielectric breakdown of the insulation part between the winding turns of the motor 3 similarly depends upon the partial discharge total number Nₜ₋ₜ·n_{pd(motor)}. If the partial discharge total number Nₜ₋ₜ·n_{pd (motor)} becomes equal to Nₜ₋ₜ·n_{pd (twist-pair)} at the inverter surge voltage ΔV₍ₘₒₜₒᵣ₎ at which the voltage peak value Vₜ₋ₜ appears between the winding turns of the motor 3, then dielectric breakdown begins to occur at the insulation part between the winding turns. Therefore, where the number of times N_{required} that an impulse voltage is applied is required for the motor 3, it is necessary to satisfy the condition “N_{required}·n_{pd(motor)}≦Nₜ₋ₜ·n_{pd(twist-pair)}” regarding the partial discharge total number (namely, the expression (1)).

In this manner, then, the insulation performance (acceptable or unacceptable) of the motor 3 can be evaluated from the n_{pd}-V characteristic illustrated in FIG. 7, the n_{pd}-V characteristic of the motor 3 and the required number of times N_{required} that an impulse voltage is applied.

If the partial discharge occurrence frequency n_{pd(motor)} of the motor 3 satisfies the conditional expression (1), then a determination of yes is made at step S010. In this instance, the product (N_{required}·n_{pd}) of the number of times N_{required} that an impulse voltage is applied and the partial discharge occurrence frequency n_{pd} is included in the insulating material available region (hatched line region) of the twisted-pair wire sample 2. Therefore, the processing advances to step S012, at which it is displayed, for example, on the display section 16 that the motor 3 is acceptable.

On the other hand, if the conditional expression (1) is not satisfied, then the product (N_{required}·n_{pd}) of the number of times N_{required} that an impulse voltage is applied and the partial discharge occurrence frequency n_{pd} exceeds the insulating material available region (hatched line region) of the twisted-pair wire sample 2. In this instance, the processing advances to step S013, at which it is displayed on the display section 16 that the motor 3 is unacceptable.

Incidentally, if the number of times N_{required} that an impulse voltage is applied required for the motor 3 is obtained actually in advance, then an insulation test of the motor 3 can be carried out as described above by a user inputting the number of times N_{required} that an impulse voltage is applied. However, it is known that, in an inverter-driven motor system, the magnitude or the occurrence frequency of an inverter surge voltage varies in response to the combination of an inverter, a cable and a motor or laying conditions of the system.

Therefore, it is not reasonable to carry out, for an inverter-driven motor system from which an actual result is not obtained as yet, an insulation test of the motor 3 using a conventional actual result for the number of times N_{required} that an impulse voltage is applied as described hereinabove. For example, if a higher speed inverter switching element is adopted, then an actual value of the number of times N_{required} that an impulse voltage is applied obtained by an inverter which uses a conventional low-speed switching element cannot be used as it is.

Therefore, where an actual value of the number of times N_{required} that an impulse voltage is applied is unavailable, if a screen image which urges the user to input at step S008 is displayed on the display section 16, then the operator would input the motor lifetime tᵢₙᵥ required for the motor 3. After the motor lifetime tᵢₙᵥ is inputted, the processing advances from step S009 to step S011, at which a calculation process for determining the number of times N_{required} that an impulse voltage is applied required for the motor 3 is carried out.

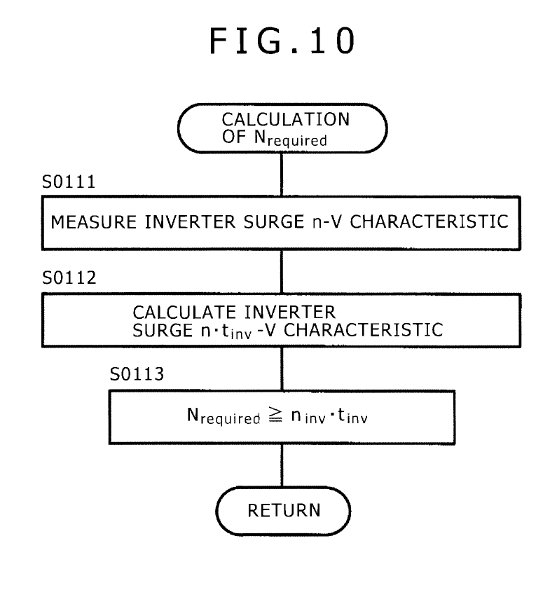

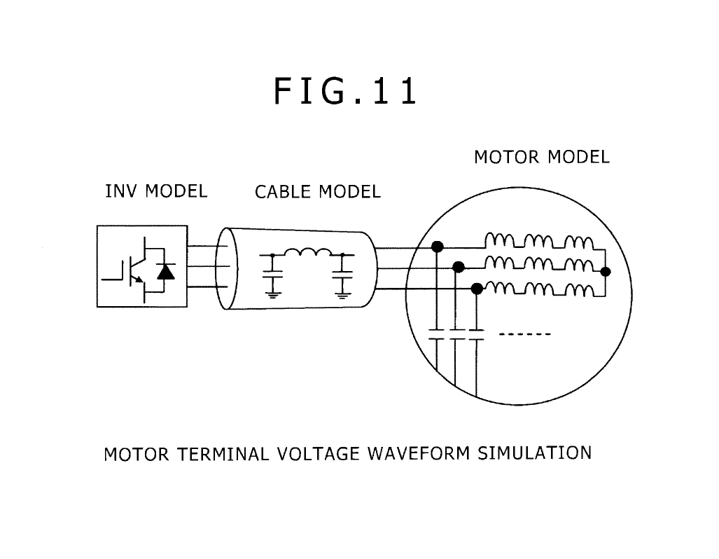

FIG. 10 illustrates an example of a detailed process at step S011. Here, the number of times N_{required} that an impulse voltage is applied is calculated using a motor terminal voltage waveform simulation. When a motor terminal voltage waveform is determined by a simulation, for example, an inverter model is simulated by a switching element, a cable model is simulated by a distributed constant circuit or a ladder-type equivalent circuit, and a motor is simulated by a ladder-type equivalent circuit as illustrated in FIG. 11.

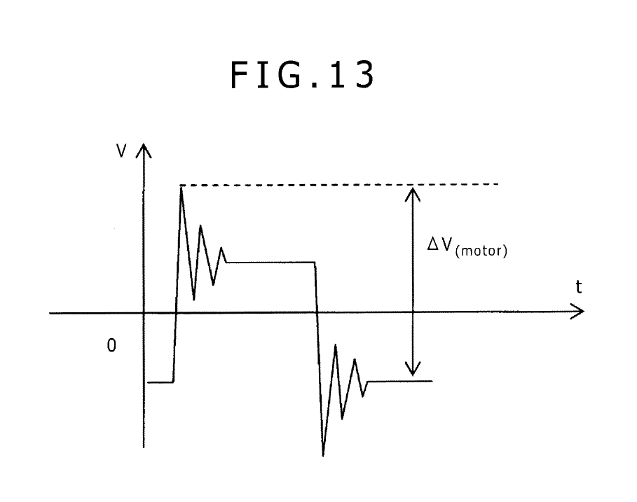

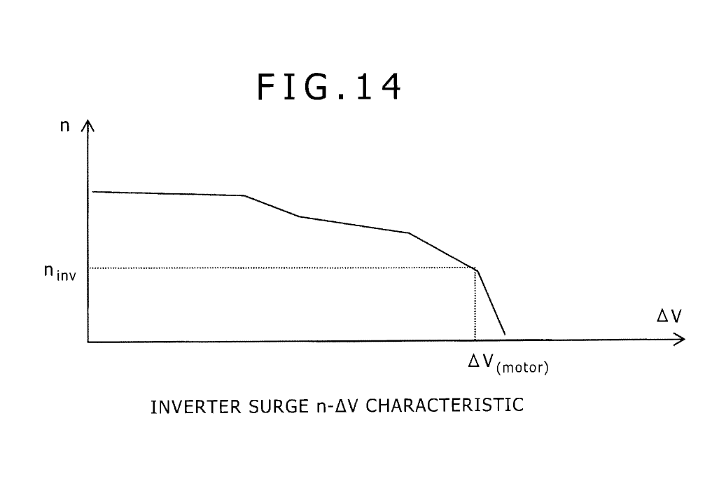

At step S0111, a motor terminal voltage waveform is calculated using a motor terminal voltage waveform simulation to determine a relationship (inverter surge n-ΔV characteristic: refer to FIG. 14) between the magnitude (refer to FIG. 13) and the occurrence frequency ₙᵢₙₑ of the steep voltage variation amount ΔV₍ₘₒₜₒᵣ₎ of the voltage waveform between motor terminals with respect to the ground. This occurrence frequency nᵢₙᵥ, represents the number of times by which ΔV₍ₘₒₜₒᵣ₎ is acquired per unit time period (one second). The result of the calculation is stored into the data collection storage section 14 of FIG. 1.

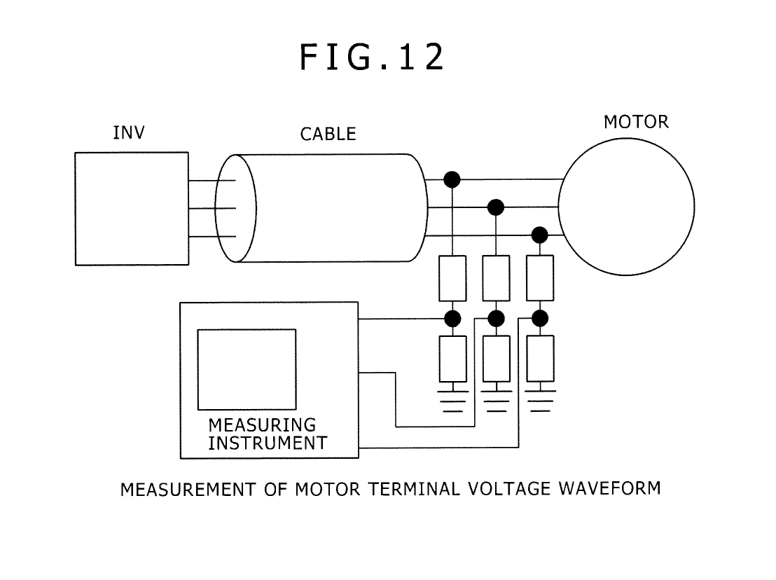

It is to be noted that, while the inverter surge n-ΔV characteristic here is determined by a motor terminal voltage waveform simulation, it may otherwise be acquired by actually measuring the motor terminal voltage waveform. Where the motor terminal voltage waveform is determined by an actual measurement, a prototype inverter, a cable and a motor are combined as shown in FIG. 12 to measure the motor terminal voltage waveform. Then, such an inverter surge n-ΔV characteristic as illustrated in FIG. 14 is determined based on the result of the measurement.

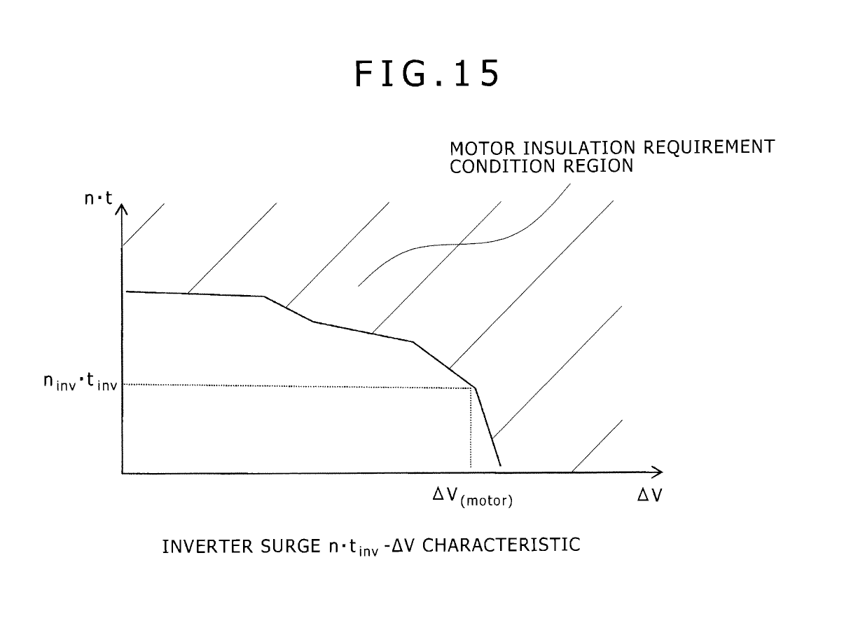

At step S0112 of FIG. 10, such an inverter surge n·tᵢₙᵥ-V characteristic as illustrated in FIG. 15 is calculated based on the inverter surge n-ΔV characteristic stored in the data collection storage section 14 and the motor lifetime tᵢₙᵥ inputted by the user. It is necessary for the motor 3 to withstand an inverter surge by the number of times greater than n·tᵢₙᵥ calculated at step S0111. Therefore, it is necessary for the number of times N_{required} that an impulse voltage is applied required for the motor 3 to satisfy the following expression (2). This corresponds to a region indicated by hatched lines in FIG. 15.

N_{required}≧nᵢₙᵥ·tᵢₙᵥ (2)

At step S0113, N_{required} which satisfies the expression (2) is set as the number of times that an impulse voltage is applied required for the motor 3. For example, N_{required} is set as N_{required}nᵢₙᵥ·tᵢₙᵥ. After the process at step S0113 ends, the processing advances to step S010 of FIG. 4.

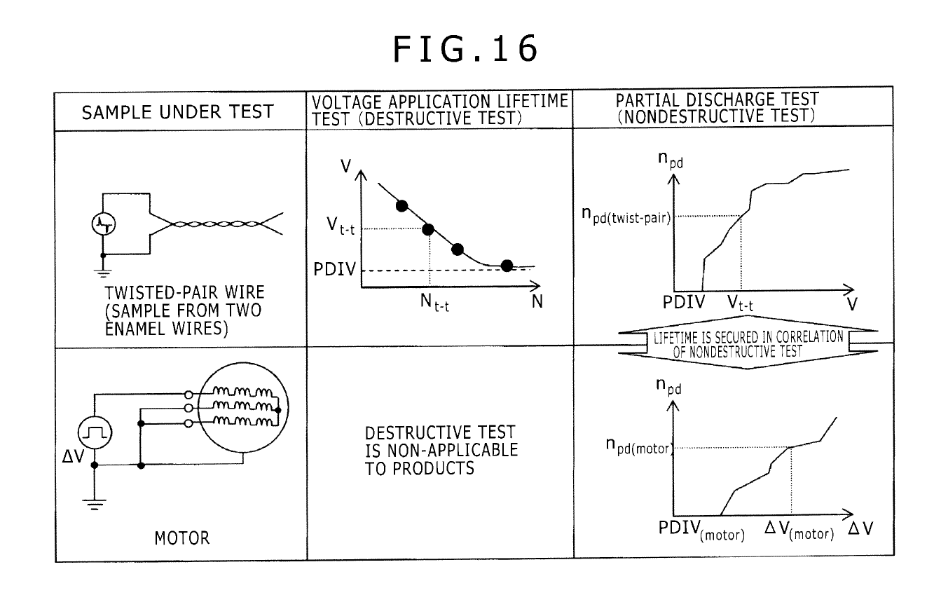

FIG. 16 illustrates a summary of contents of an examination carried out in the insulation inspection flow illustrated in FIG. 4. For the twisted-pair wire sample 2 which is a simulation sample, a destructive test of applying the impulse voltage 21 repetitively until insulation breakdown occurs and a partial discharge test (measurement of the n_{pd(twist-pair)}-V characteristic) which is a nondestructive test are carried out. For the motor 3, only a partial discharge test (measurement of the n_{pd(motor)}-V characteristic) which is a nondestructive test is carried out. Further, a correlation between the partial discharge tests is utilized to determine whether or not the product N_{required}·n_{pd (motor)} relating to the motor 3 falls in the insulating material available region (hatched line region) of the twisted-pair wire sample 2. Therefore, the lifetime of the motor 3 can be guaranteed even if a voltage application lifetime test (destructive test) in which the motor 3 as a product is used is not carried out.

Further, as described in the foregoing description of step S011, in the insulation inspection apparatus of the present embodiment, the number of times N_{required} that an impulse voltage is applied can be determined appropriately also in an inverter-driven rotary electric machine system with regard to which no performance in the past is available. Therefore, the insulation inspection apparatus of the present embodiment can be applied to various inverter-driven rotary electric machine systems.

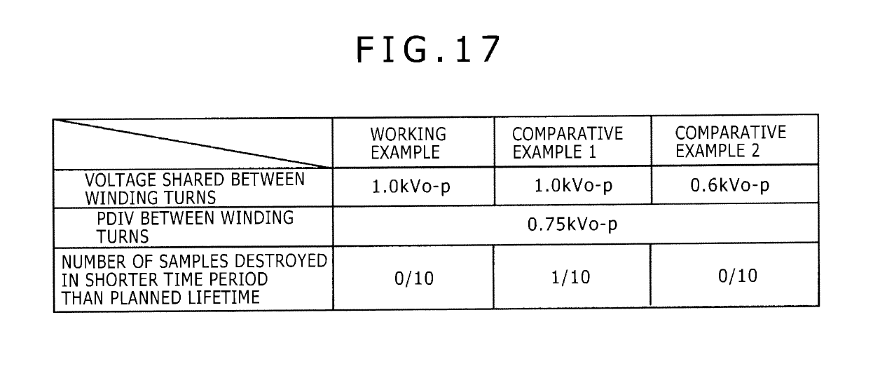

The lifetime of a motor whose insulation inspection was carried out using the insulation inspection method of the present embodiment is illustrated as a working example of FIG. 17. Further, the lifetime in the case where a motor was designed and fabricated based only on the V-N characteristic of an enamel wire without using the insulation inspection method for an inverter-driven low-voltage rotary machine of the present invention is illustrated as a comparative example 1. Furthermore, the lifetime of a motor where insulation design, fabrication and inspection which do not permit occurrence of partial discharge were carried out is illustrated as a comparative example 2.

Where the inspection method of the present invention is used as in the working example, no sample suffered from breakdown in a shorter period of time than a planned lifetime was found.

On the other hand, in the comparative example 1, since the motor is designed based only on the V-N characteristic of the enamel wire such that Nₜ₋ₜ is longer than the planned lifetime (N_{required}) also such a motor that exhibits a relationship of “n_{pd(motor)}>Nₜ₋ₜ·n_{pd(twist-pair)}/N_{required}” comes to exist. However, since the inspection method of the present invention is not used, also such a motor that exhibits the relationship of “n_{pd(motor)}>Nₜ₋ₜ·n_{pd(twist-pair)}/N_{required}” is determined as acceptable in the test and no rejected product can be found out. As a result, a sample which breaks down in a shorter period of time than the planned lifetime was found out.

On the other hand, in the motor for which a conventional insulation design and inspection method for a low-voltage rotary electric machine which does not permit occurrence of partial discharge are used, a sample which breaks down in a shorter period of time than the planned lifetime did not appear as seen in the comparative example 2. However, in order to prevent occurrence of partial discharge, the voltage which can be applied to the motor had to be set to 0.6 Vo-p by suppression by 40% with respect to the working example, and the motor was not able to cope with a steep high surge voltage for the inverter.

It is to be noted that, in the insulation test illustrated in FIG. 4, such a configuration that characteristics illustrated in FIGS. 5 to 7 relating to the twisted-pair wire sample 2 are acquired by the insulation inspection apparatus 1 is adopted. However, the characteristics may otherwise be acquired separately and stored in the storage section 4 in advance. In this instance, only the motor 3 is connected to the insulation inspection apparatus 1, and it is only necessary as a measuring function to be able to measure at least the n_{pd}-V characteristic of the motor 3. Further, if data (Nₜ₋ₜ, n_{pd(twist-pair)}) acquired with regard to a plurality of applied voltages V, namely, such characteristic curves as illustrated in FIGS. 5 to 7, are stored in advance in the storage section 4, then a plurality of motors of different types having different voltage specifications can be inspected.

The way of thinking described hereinabove in connection with the insulation inspection method can be applied also to a design method of an inverter-driven low voltage rotary electric machine. In particular, an impulse voltage simulating a voltage which appears between rotary electric machine winding turns upon application of an inverter surge voltage is applied to the twisted-pair wire sample 2 which uses an insulated wire same as that of the rotary electric machine winding. The number of times Nₜ₋ₜ that an impulse voltage is applied until the twisted-pair wire sample 2 suffers from insulation breakdown is then measured to determine such a V-N characteristic as illustrated in FIG. 5. Similarly, the impulse voltage described above is applied to measure the partial discharge occurrence frequency n_{pd(twist-pair)} by which partial discharge occurs per one time application, thereby determining such an n_{pd}-V characteristic as illustrated in FIG. 6. Then, the partial discharge occurrence frequency n_{pd(motor)} between the winding turns is set so as to satisfy an expression “n_{pd(motor)}≦Nₜ₋ₜ·n_{pd(twist-pair)}/N_{required}” with respect to the number of times N_{required} that an impulse voltage is applied required for the motor 3.

Consequently, an inverter-driven rotary electric machine which permits occurrence of partial discharge between winding turns, particularly, a low-voltage rotary electric machine of 700 Vrms or less, can be provided. Further, for example, in the case of a motor which uses a partial discharge-withstanding enamel wire having a fixed withstanding property to partial discharge, conventionally an inspection method cannot be applied. Therefore, it is liable to be inclined to perform insulation design having some margin. However, if the insulation inspection method of the present embodiment is used, then a motor which satisfies a required lifetime while avoiding an excessive insulation performance can be designed. Consequently, also fit is possible to achieve miniaturization of a motor.

While various embodiments and modifications are described in the foregoing description, the embodiments may be used singly or in combination. This is because the effects by each of the embodiments can be achieved singly or synergistically. Further, unless the characteristics of the present invention are spoiled, the present invention is not restricted to the embodiments described hereinabove. Also other modes which are conceivable within the technical scope of the present invention are included in the scope of the present invention.

1. An inverter-driven rotary electric machine wherein,
where, in an insulation sample which is formed from an insulated wire same as the wire of a winding of the rotary electric machine and indicates an N-V characteristic in which the number of times that an impulse voltage is applied till insulation breakdown at a voltage peak value V is N, the number of times that an impulse voltage is applied till insulation breakdown when a first impulse voltage is applied is represented by Nₜ₋ₜ, the first impulse voltage simulating a voltage which occurs between winding turns of the rotary electric machine upon application of an inverter surge voltage, and an occurrence frequency of partial discharge which occurs per one time application is represented by n_{pd},
a partial discharge occurrence frequency n_{pd(motor)} between the winding turns is set so as to satisfy, with respect to a required number of times N_{required} that an impulse voltage is applied, the following expression (A1):
n_{pd(motor)}≦Nₜ₋ₜ·n_{pd}/N_{required} (A1)

2. The inverter-driven rotary electric machine according to claim 1, wherein
the number of times N_{required} that an impulse voltage is applied is set so as to satisfy, where an occurrence frequency of the inverter surge voltage per a unit time period is represented by nᵢₙᵥ and an operating time period required for the rotary electric machine is represented by tᵢₙᵥ, the following expression (A2):
N_{required}≧nᵢₙᵥ·tᵢₙᵥ (A2)

3. The inverter-driven rotary electric machine according to claim 1 or 2, wherein a rated voltage is set to a value of 700 Vrms or less.

4. An insulation inspection method for an inverter-driven rotary electric machine, comprising:
a step of applying, to an insulation sample which is formed from an insulated wire same as the wire of a winding of the rotary electric machine and indicates an N-V characteristic in which the number of times that an impulse voltage is applied till insulation breakdown at a voltage peak value V is N, a first impulse voltage simulating a voltage which occurs between winding turns of the rotary electric machine upon application of an inverter surge voltage to measure the number of times Nₜ₋ₜ that an impulse voltage is applied until the insulation sample suffers from insulation breakdown;
a step of applying the first impulse voltage to the insulation sample to measure an occurrence frequency n_{pd} of partial discharge which occurs per one time application;
a step of applying a second impulse voltage simulating the inverter surge voltage to the rotary electric machine to measure a partial discharge occurrence frequency n_{pd(motor)} between the winding turns which occurs per one time application; and
determining that an insulation performance of the rotary electric machine is acceptable when the partial discharge occurrence frequency n_{pd(motor)} satisfies the following expression (A1) with respect to the number of times N_{required} that an impulse voltage is applied required for the rotary electric machine:
n_{pd(motor)}≦Nₜ₋ₜ·n_{pd}/N_{required} (A1)

5. The insulation inspection method for an inverter-driven rotary electric machine according to claim 4, wherein
the number of times N_{required} that an impulse voltage is applied is set so as to satisfy, where an occurrence frequency of the inverter surge voltage per a unit time period is represented by ₙᵢₙₑ and an operating time period required for the rotary electric machine is represented by tᵢₙᵥ, the following expression (A2):
N_{required}≧nᵢₙᵥ·tᵢₙᵥ (A2)

6. An insulation inspection apparatus for an inverter-driven rotary electric machine, comprising:
a storage section in which the number of times Nₜ₋ₜ that an impulse voltage is applied until an insulation sample which uses an insulating wire same as the wire of a rotary electric machine winding suffers from insulation breakdown and an occurrence frequency n_{pd} of partial discharge which occurs per one time application are stored, the number of times Nₜ₋ₜ that an impulse voltage is applied and the partial discharge occurrence frequency n_{pd} being measured when a first impulse voltage simulating a voltage which appears between winding turns of the rotary electric machine upon application of an inverter surge voltage is applied to the insulation sample;
an impulse power supply configured to apply a second impulse voltage simulating the inverter surge voltage to the rotary electric machine;
a measurement section configured to measure a partial discharge occurrence frequency n_{pd(motor)} between the winding turns of the rotary electric machine to which the second impulse voltage is applied; and
an acceptance decision processing section configured to determine that an insulation performance of the rotary electric machine is acceptable when the partial discharge expression (A1) with respect to the number of times N_{required} that an impulse voltage is applied required for the rotary electric machine:
n_{pd(motor)}≦Nₜ₋ₜ·n_{pd}/N_{required} (A1)

7. An insulation inspection apparatus for an inverter-driven rotary electric machine, comprising:
an impulse power supply capable of selectively outputting one of a first impulse voltage simulating a voltage which is generated between winding turns of a rotary electric machine upon application of an inverter surge voltage and a second impulse voltage simulating the inverter surge voltage;
a changeover mechanism configured to switchably connect, to the impulse power supply, one of an insulation sample and the rotary electric machine, the insulation sample being formed from an insulated wire same as the wire of a winding of the rotary electric machine and indicating an N-V characteristic in which the number of times that an impulse voltage is applied till insulation breakdown at a voltage peak value V is N;
an insulation sample characteristic measurement section configured to measure the number of times Nₜ₋ₜ that an impulse voltage is applied and an occurrence frequency n_{pd} of partial discharge which occurs per one time application, the number of times Nₜ₋ₜ that an impulse voltage is applied and the occurrence frequency n_{pd} being obtained by applying the first impulse voltage to the insulation sample;
a rotary electric machine characteristic measurement section configured to measure the partial discharge occurrence frequency n_{pd(motor)} obtained by applying the second impulse voltage to the rotary electric machine; and
an acceptance decision processing section configured to determine that an insulation performance of the rotary electric machine is acceptable when the partial discharge occurrence frequency n_{pd(motor)} satisfies the following expression (A1) with respect to the number of times N_{required} that an impulse voltage is applied required for the rotary electric machine:
n_{pd(motor)}≦Nₜ₋ₜ·n_{pd}/N_{required} (A1)

8. The insulation inspection apparatus for an inverter-driven rotary electric machine according to claim 6 or 7, wherein
the number of times N_{required} that an impulse voltage is applied is set so as to satisfy, where an occurrence frequency of the inverter surge voltage per a unit time period is represented by nᵢₙᵥ and an operating time period required for the rotary electric machine is represented by tᵢₙᵥ, the following expression (A2):
N_{required}≧nᵢₙᵥ·tᵢₙᵥ (A2)
